(19) United States
(12) Patent Application Publication
(10) Pub. No.: US 2007/0054497 A1
(43) Pub. Date: Mar. 8, 2007

(54) Method for preventing contamination and lithographic device

(76) Inventors: Markus Weiss, Aalen (DE); Marco Wedowski, Aalen (DE); Bas M Mertens, Den Haag (NL); Bas T Wolschrijn, Amsterdam (NL); Bart H.A.M. Van Mierlo, Maassluis (NL); Norbert B Koster, Delft (NL); Jan Van Elp, Delft (NL); Anton E Duiserwinkel, Delft (NL); Annemieke Van De Runstraat, Zoetermeer (NL)

Correspondence Address: Hudak Shunk & Farine Co, Suite 307, 2020 Front Street, Cuyahoga Falls, OH, 44221, US

(21) Appl. No.: 10/555,562

(22) PCT Filed: May 6, 2004
(86) PCT No.: PCT/EP04/04824

§ 371 Date: Aug. 24, 2006

(30) Foreign Application Priority Data
May 9, 2003 (DE) 103 21 103.9

(51) Int. Cl. H01L 21/00; G03G 15/00; H01L 21/31

(52) U.S. Cl. 438/758; 355/133; 977/901; 257/E21.023

(57) ABSTRACT

The invention relates to a method for preventing contamination of the surfaces of reflective optical elements for the soft X-ray and EUV wavelength range during their irradiation at operating wavelength in an evacuated closed system having a residual gas atmosphere, said elements comprising a cover layer consisting of at least one transition metal. According to said method a residual gas atmosphere is adjusted. The aim of the invention is to prevent a degradation of the surfaces by deposition of carbon and by surface oxidation. For this purpose, both a reducing gas or gas mixture and a gas or gas mixture containing oxygen atoms are introduced. In conjunction with the cover layer of the reflective optical element that consists of a transition metal a degradation of the surface is effectively prevented

The invention concerns a method for preventing contamination of the surfaces of reflective optical elements for the soft X-ray and EUV wavelength range with a cover layer of at least one transition metal while being irradiated at the operating wavelength in an evacuated closed system having a residual gas atmosphere, in which a particular residual gas atmosphere is established.

Moreover, the invention concerns an EUV lithography device with at least one reflective optical elements for the soft X-ray and EUV wavelength range with a cover layer of at least one transition metal, arranged in an evacuable housing, as well as a method for production of electronic microcomponents.

Optical reflective elements for the soft X-ray to EUV wavelength range (i.e., wavelengths between 5 nm and 20 nm), such as photomasks or multilayer mirrors, are required in particular for use in EUV lithography of semiconductor components. Typical EUV lithography devices have eight or more reflective optical elements. In order to still achieve a sufficient overall intensity of the working radiation, the mirrors have to have the highest possible reflectivities, since the overall intensity is proportional to the product of the reflectivities of the individual mirrors. These high reflectivities should be retained by the reflective optical elements if possible throughout their lifetime. Furthermore, the homogeneity of the reflectivity across the surface of the reflective optical element must be preserved for the entire lifetime. The reflectivity and the lifetime of these reflective optical elements are especially impaired by contamination of the surface during exposure to the operating wavelength in the form of carbon deposits and by oxidation of the surface.

The reflective optical elements contaminate during operation by residual gases from the vacuum atmosphere. In this process, molecules of residual gas become adsorbed on the surfaces of the reflective optical elements and are broken up by the high-energy photon radiation through emission of photoelectrons. When hydrocarbons are present in the residual gas atmosphere, a carbon layer is thus formed, which diminishes the reflectivity of a reflective optical element by around 1% per nm of thickness. At a partial pressure of hydrocarbons of around 10⁻⁹ mbar, a layer of 1 nm thickness will be formed already after around 20 hours. Since, for example, EUV lithography devices with a reflectivity loss of 1% per reflective optical element no longer allow the necessary production pace, this contamination layer must be removed by a cleaning process which typically takes up to 5 hours. Furthermore, such a cleaning process is liable to harm the surface of the reflective optical element, for example, to roughen or oxidize it, and therefore the initial reflectivity cannot be regained.

Oxygen-containing residual gas molecules can contribute to oxidation of the surfaces. In this way, the unprotected surface of a reflective optical element might become disrupted within a few hours.

According to WO 02/052061 A1 and US 2001/0051124 A1, one strives to avoid oxidation by adding hydrocarbons in with the residual gas atmosphere, especially alcohol. According to these patents, although it is expected that a self-terminating carbon layer will be deposited in this way on the surface of a reflective optical element, long-term experiments of over 100 hours have shown that the carbon layer continues to grow slowly.

US 2002/0084425 A1 teaches that the carbon contamination can be removed by adding a cleaning gas. As the cleaning gas, oxygen, hydrogen and water are proposed. One problem, however, is that not only is the carbon contamination layer removed, but also at times an oxidation of the surface lying under the contamination may be produced.

In US 2001/0053414 A1 it is proposed to add, in particular, ethanol and water in a 2:1 ratio to the residual gas atmosphere in order to accomplish a simultaneous cleaning and protection of the surfaces.

In EP 1 065 568 A2 is described a protective layer of ruthenium, for example, which considerably reduces the oxidation susceptibility. For a reflective optical element with such a cover layer, given a partial pressure of 10⁻⁶ mbar for water and an energy density of 10 mW/mm2, the oxidation rate can be reduced to 0.03% per hour. This extends the lifetime of a reflective optical element to around 30 hours. However, for economical use of the reflective optical element in, say, an EUV lithography device, one must achieve lifetimes of several years.

The problem of the present invention is to overcome the drawbacks of the prior art.

This problem is solved by a method per claim 1 as well as a device per claim 11 and a method per claim 14.

Surprisingly, it has been found that through the suitable choice of the material of a cover layer for reflective optical elements as well as a reducing and an oxidizing gas or gas mixture, a synergistic effect is achieved, so that neither does a carbon layer grow during operation, nor does the surface of the reflective optical element become oxidized. This synergistic effect is probably due to redox reactions and catalytic effects occurring at the cover layer based on transition metal, which are independent of the intensity of the incoming radiation over broad ranges.

One conceivable reaction mechanism consists in that the oxidizing gas or gas mixture at room temperature oxidizes the surface of the transition metal M to a supersaturated oxide of the form MOₓO. If EUV radiation or soft X-rays are beamed in, the reducing gases or gas mixtures react with the supersaturated metal oxide MOₓO to form oxidized cleavage products, so that the reducing gas or gas mixture does not cause any contamination. The supersaturated metal oxide MOₓO will be reduced to a lower oxidation stage, preventing the oxidation of the transition metal. The oxidizing gas or gas mixture oxidizes the transition metal of the lower oxidation stage back to an active supersaturated oxide MOₓO. In this way, a dynamic equilibrium is produced, which is independent of the radiation intensity over broad ranges.

Thanks to the method of the invention, the lifetime of reflective optical elements is increased so much that an economical application in EUV lithography devices becomes possible. Frequent cleaning cycles are avoided. As a result, there is also less risk of damaging the surface of the reflective optical element by too aggressive cleaning, which would lead to reflectivity losses or lateral inhomogeneities in the radiation density.

In one preferred embodiment, H₂O and O₂ are introduced as the gas or gas mixture having oxygen atoms, because these, unlike peroxides, for example, are not only more safe, but also more economical.

In theory, any reducing gas or gas mixture can be used, especially hydrogen, nitrogen, carbon monoxide and hydrocarbons. In particular, hydrocarbons are preferred for work safety reasons. It has been found to be of advantage to employ hydrocarbons having a boiling point below 150° C. and a molecular weight under 120 g/mol, since large partial pressures can be achieved with such hydrocarbons and therefore the process can be more easily controlled.

The critical factor in choosing a suitable hydrocarbon or a suitable mixture of hydrocarbons is that the surface of the particular reflective optical element be well covered. The adhesion of the molecules to the particular surface is significant for this. For example, the molecules should not have too low a molar mass.

The gas or gas mixture containing the oxygen atom should also cover the surface of the particular reflective optical element well.

Moreover, the adding of additional gases, such as noble gases, does not have any negative influence on the method of the invention.

In structural terms, it has proven to be advantageous for the hydrocarbon or hydrocarbons to contain oxygen atoms. It has also proven to be advantageous for the hydrocarbon or hydrocarbons to have at least one double bond. It is especially beneficial for the hydrocarbon or hydrocarbons to have one or more C═O and/or OC═O and C≡O groups.

Especially preferred as the hydrocarbons are, for example, alcohols, aldehydes, ketones, ethers, esters or carboxylic acids. In an especially preferred embodiment of the invented method, methyl methacrylate (MMA) is introduced as the hydrocarbon.

Another important parameter for the efficiency of the invented method of preventing contamination is the choice of the transition metal for the cover layer of the reflective optical elements. Especially beneficial are cover layers of ruthenium, rhodium, palladium, silver, rhenium, osmium, iridium, platinum and/or gold or their compounds, alloys, or mixtures. These transition metals in fact only oxidize on the surface, which is necessary for a constant reflectivity. Especially preferred are ruthenium, rhodium, rhenium and iridium, which exhibit slight absorption in the EUV to the soft X-ray wavelength range.

Advantageously, the ratio of the partial pressures of MMA to H₂O lies between 1:10 and 1:1000 and the ratio of the partial pressures of MMA to O₂ lies between 1:1000 and 1:100000. These pressure ratios have proven to work especially well with a cover layer of ruthenium, which shows especially good catalytic effects.

If the gases and the partial pressure ratios are properly chosen, the present method can also be used to perform a gentle cleaning of the surface of reflective optical elements.

It has proven to be of advantage for the partial pressure of the MMA to be at most 10⁻⁷ mbar. Otherwise, a carbon contamination might result. But in order not to result in easy oxidations, it should be at least 10⁻⁹ mbar. The optimal choice of the partial pressure in any case depends on the specific choice of the cover layer material or the oxidizing gas or gas mixture.

When choosing the partial pressure ratio one must also consider that the partial pressure for hydrocarbons of rather low molar mass should be somewhat higher and that for hydrocarbons of rather higher molar mass should be somewhat less than that of oxygen and water.

The invention shall now be explained by means of the following figures and examples.

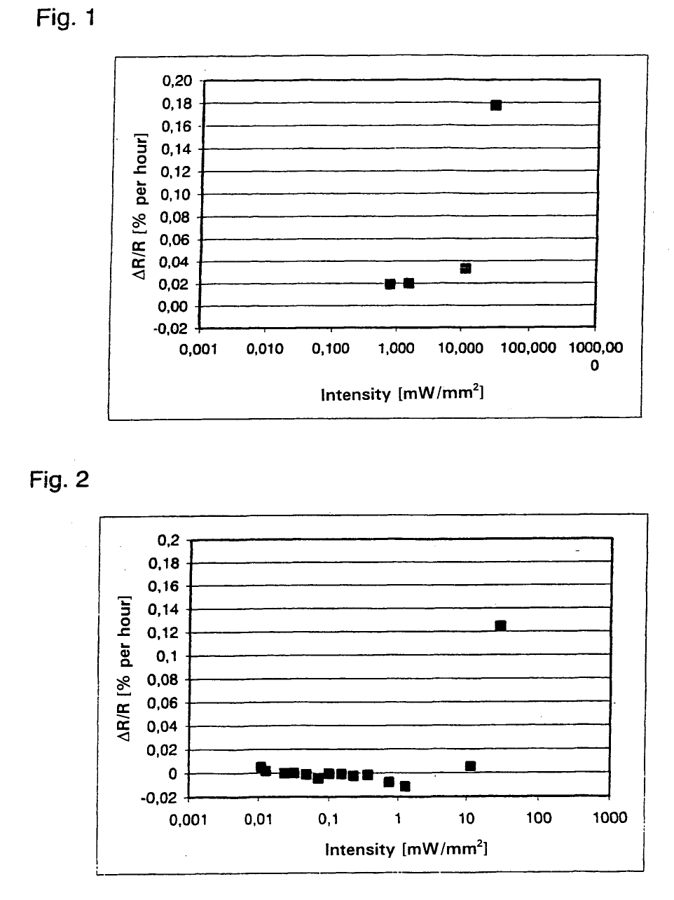

FIG. 1 reflectivity loss per hour as a function of the irradiation energy density for a first ambient atmosphere according to the invention;

FIG. 2 reflectivity loss per hour as a function of the irradiation energy density for a second ambient atmosphere according to the invention;

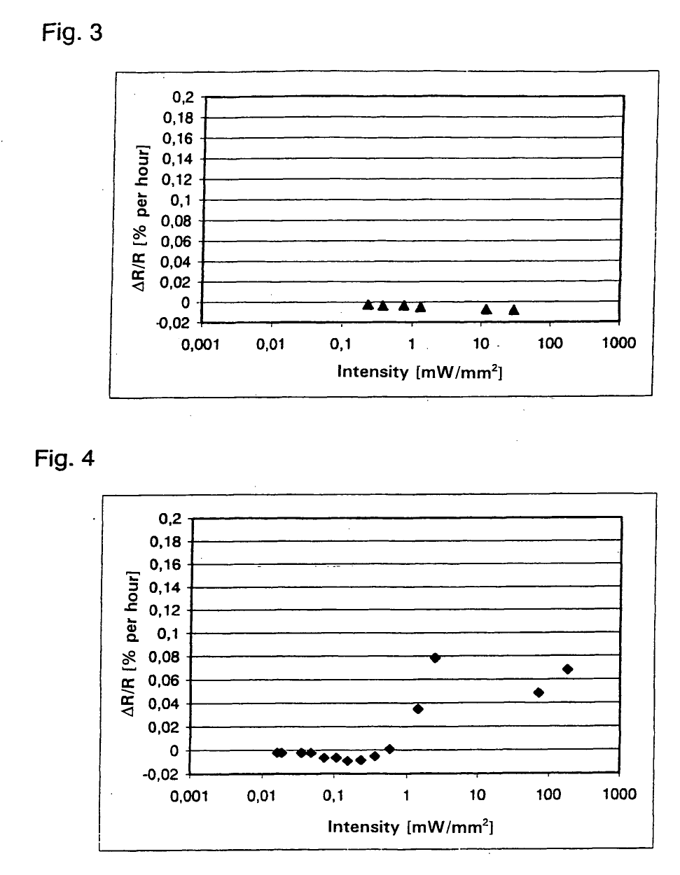

FIG. 3 reflectivity loss per hour as a function of the irradiation energy density for the second ambient atmosphere according to the invention with a different irradiation time;

FIG. 4 reflectivity loss per hour as a function of the irradiation energy density for a first ambient atmosphere not according to the invention;

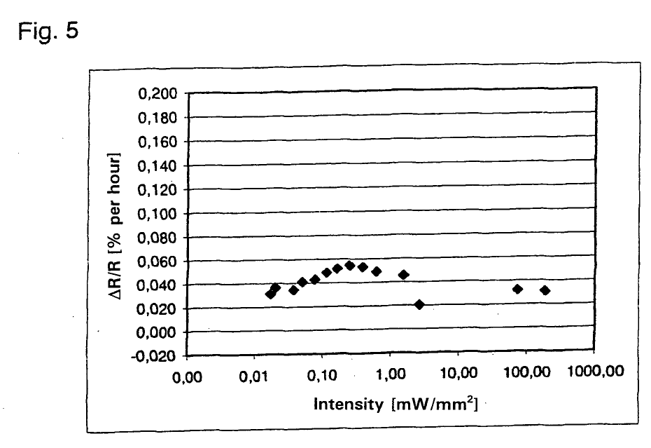

FIG. 5 reflectivity loss per hour as a function of the irradiation energy density for a second ambient atmosphere not according to the invention;

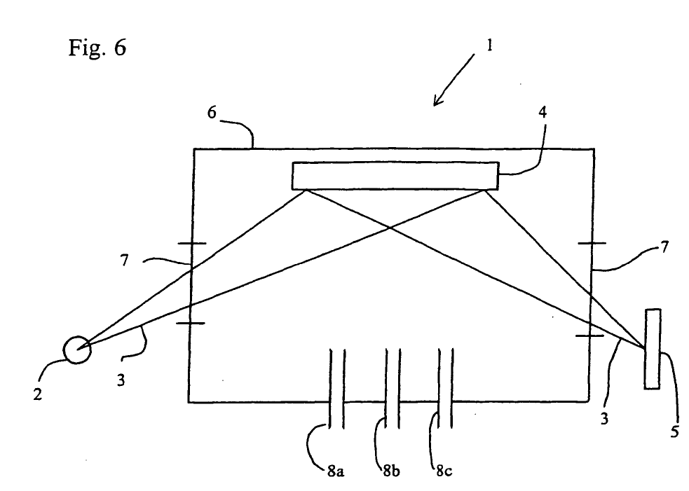

FIG. 6 basic layout of an EUV lithography device;

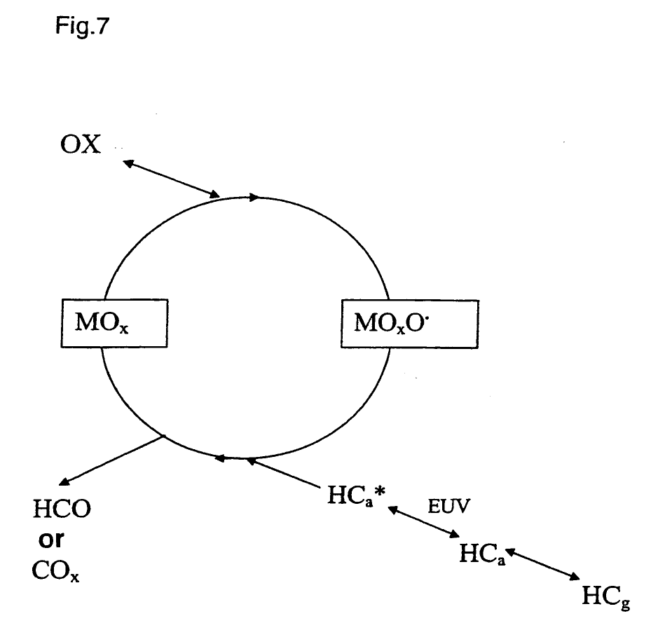

FIG. 7 basic layout of the reaction mechanism.

FIG. 1 shows the relative reflectivity loss per hour as a function of the energy density of the irradiation for an H₂O partial pressure of 1.5×10⁻⁶ mbar, an O₂-partial pressure of 5×10⁻⁵ mbar, and a MMA-partial pressure of 0.7×10⁻⁸ mbar. The experiment was run for 50 hours. It is clearly evident that a significant reflectivity loss per hour is observed only after an energy density of over 10 mW/mm². This effect is even present for partial pressures of 1.7×10⁻⁵ mbar for H₂O, 3.9×10⁻⁴ mbar for O₂, and 1.1×10⁻⁸ mbar for MMA, as the relative hourly reflectivity loss increases sharply only after 10 mW/mm² (see FIG. 2). This experiment series was run over 40 hours. Under the same partial pressure ratios a second measurement series was carried out over 71 hours. Here, even for energy densities of much more than 10 mW/mm², there is still no significant hourly relative reflectivity loss to be found (see FIG. 3). All three measurements were performed with reflective optical elements with a ruthenium cover layer at an operating wavelength of 13.5 nm.

For comparison, one should first consider FIG. 4. The measurements here were carried out with a water vapor partial pressure of 1×10⁻⁶ mbar and an oxygen partial pressure of 5×10⁻⁵ mbar. The MMA portion was no longer measurable. These measurements were run over 60 hours. Thus, when the MMA portion is too low, one can say that significant relative reflectivity changes per hour will be noticed already after 1 mW/mm². In the critical range for EUV lithography applications between 1 and 10 mW/mm², the lifetime of individual reflective optical elements can be lengthened up to a hundredfold with the help of the present invention.

FIG. 5 shows, for further comparison, the measurement results obtained for 10⁻⁷ mbar water vapor partial pressure, 9.1×10⁻⁹ mbar oxygen partial pressure, and <10⁻⁹ mbar MMA partial pressure over 80 hours. The relative reflectivity loss per hour, especially noticeable from 0.001 mW/mm² to around 1 mW/mm², is attributable to the growth of a carbon layer. This has negative impact on the reflectivity and is effectively suppressed by the present invention.

FIG. 6 shows, as an example, a greatly simplified EUV lithography device 1 in schematic layout. From an EUV radiation source 2, the radiation 3 impinges on a photomask 4 with a ruthenium cover layer, from which the radiation 3 is projected onto a wafer 5. The photomask 4 is arranged in an evacuable housing 6, having two EUV beam paths 7. The supply line 8a for H₂O, the supply line 8b for O₂ and the supply line 8c for MMA discharge in the region of the photomask 4. Not shown are pressure regulators, in order to easily adjust the desired partial pressure ratios. It should be noted that the supply lines 8a, b, c discharge in the region of, but not immediately at the photomask 4, so that the three gases are present at the surface of the photomask as the most homogeneous mixture possible.

FIG. 7 shows schematically a possible reaction mechanism for the method of the invention. This involves a cover layer material of a transition metal M, a hydrocarbon HC as the reducing gas, and oxygen OX as the oxidizing gas. The gaseous hydrocarbon HCg is adsorbed onto the surface of the cover layer (HCa). The adsorbed hydrocarbon is excited by incident EUV radiation. Both the adsorption and the excitation are reversible processes (double arrow). Meanwhile, the oxygen has reacted with MOₓ (x=0, 1, 2) present on the surface to form supersaturated MOₓO, which involves an oxygen radical for one of the oxygen atoms. This supersaturated MOₓO reacts with the excited adsorbed hydrocarbon to yield carbon monoxide or carbon dioxide COₓ, as well as oxidized hydrocarbons HCO. In this process, the MOₓO is reduced back to MOₓ.

If too little oxygen is present, the hydrocarbon will grow into a contamination layer on the surface of the cover layer. This is intensified by high radiation intensity. If not enough hydrocarbon is present, an oxidation of MOₓO to MOₓ₊₁ takes place, which is likewise intensified by higher radiation intensity. This oxidation presumably occurs also via reaction with secondary electrons. The partial pressures of oxygen and hydrocarbon should be designed with a view to the maximum desired or achieved radiation intensities. For when the radiation intensities are lower, neither the threshold of too little oxygen nor that of too little hydrocarbon will be passed. The process is then independent of the intensity in this intensity range.

The stability of the process over large ranges of radiation intensity has, in particular, the major benefit that it becomes possible to adjust a particular atmosphere for the interior of an overall lithography device or an overall optical element—regardless of the radiation intensities prevailing at the individual optical elements.

1. A method for preventing contamination on surfaces of reflective optical elements for the soft X-ray and EUV wavelength range with a cover layer having one or more transition metals while being irradiated at the operating wavelength in an evacuable closed system having a residual gas atmosphere, comprising the steps of: establishing a particular residual gas atmosphere, and introducing a reducing gas or gas mixture as well as a gas or gas mixture having oxygen atoms.

2. The method per claim 1, wherein a gas mixture of O₂ and H₂O is introduced.

3. The method per claim 1, wherein at least one hydrocarbon is introduced as the reducing gas or gas mixture.

4. The method per claim 1, wherein a hydrocarbon containing oxygen is introduced.

5. The method per claim 1, wherein a hydrocarbon with at least one double bond is introduced.

6. The method per claim 1, wherein a hydrocarbon with at least one C═O, one OC═O or a C≡O group is introduced.

7. The method per claim 1, wherein the method is carried out on a reflective optical element with a cover layer of ruthenium, rhodium, palladium, silver, rhenium, osmium, iridium, platinum and/or gold or a mixture or a compound or an alloy of the aforesaid transition metals.

8. The method per claim 1, wherein methyl methacrylate (MMA) is introduced as the hydrocarbon.

9. The method per claim 8, wherein a ratio of partial pressures of MMA to H₂O lies between 1:10 and 1:1000 and a ratio of partial pressures of MMA to O₂ lies between 1:1000 and 1:100000.

10. The method per claim 8, wherein a partial pressure of the MMA is at most 10⁻⁷ mbar and at least 10⁻⁹ mbar.

11. An EUV lithography device comprising: at least one reflective optical element for the soft X-ray or extreme ultraviolet wavelength range with a cover layer made from at least one transition metal in an evacuable housing and at least two supply lines which discharge in the region of the reflective optical element and serve to supply a gas or gas mixture having oxygen atoms and at least one reducing gas or gas mixture.

12. The EUV lithography device per claim 11, wherein it has three supply lines for the supplying of O₂ and H₂O and a hydrocarbon.

13. The EUV lithography device per claim 12, wherein the reflective optical element has a cover layer of ruthenium, rhodium, palladium, silver, rhenium, osmium, iridium, platinum and/or gold or a mixture or a compound or an alloy of the aforesaid transition metals.

14. A method for production of microelectronic components, comprising the steps of: producing at least one microelectronic component with an EUV lithography device comprising at least one reflective optical element for the soft X-ray or extreme ultraviolet wavelength range with a cover layer made from at least one transition metal in an evacuable housing and at least two supply lines which discharge in the region of the reflective optical element and serve to supply a gas or gas mixture having oxygen atoms and at least one reducing gas or gas mixture.

15. The method per claim 2, wherein at least one hydrocarbon is introduced as the reducing gas or gas mixture.

16. The method per claim 15, wherein a hydrocarbon containing oxygen is introduced.

17. The method per claim 16, wherein a hydrocarbon with at least one C═O, one OC═O or a C≡O group is introduced.

18. The method per claim 17, wherein the method is carried out on a reflective optical element with a cover layer of ruthenium, rhodium, palladium, silver, rhenium, osmium, iridium, platinum and/or gold or a mixture or a compound or an alloy of the aforesaid transition metals.

19. The method per claim 18, wherein methyl methacrylate (MMA) is introduced as the hydrocarbon.

20. The method per claim 19, wherein a ratio of partial pressures of MMA to H₂O lies between 1:10 and 1:1000 and a ratio of partial pressures of MMA to O₂ lies between 1:1000 and 1:100000; and wherein a partial pressure of the MMA is at most 10⁻⁷ mbar and at least 10⁻⁹ mbar.
